(19) United States
(12) Patent Application Publication
(10) Pub. No.: US 2026/0293593 A1
(43) Pub. Date: Sep. 24, 2026

(54) SUBSTRATE PROCESSING APPARATUS

(71) Applicant: EBARA CORPORATION, Tokyo (JP)

(72) Inventors: Mitsuru MIYAZAKI, Tokyo (JP); Hiroshi SOTOZAKI, Tokyo (JP); Kenichi TAKEBUCHI, Tokyo (JP); Takuya INOUE, Tokyo (JP); Shozo TAKAHASHI, Tokyo (JP); Ryohei ISHII, Tokyo (JP)

(21) Appl. No.: 19/128,505

(22) PCT Filed: Nov. 6, 2023
(86) PCT No.: PCT/JP2023/039880

§ 371 Date: Jun. 4, 2026

(30) Foreign Application Priority Data
Nov. 18, 2022 (JP) 2022-185102

(51) Int. Cl. H10P 72/30; B24B 37/10; B24B 37/34; H10P 72/00; H10P 72/76

(52) U.S. Cl. CPC H10P 72/3206; B24B 37/10; B24B 37/345; H10P 72/0428; H10P 72/7602

(57) ABSTRACT

The substrate processing apparatus includes a plurality of polishing modules (1A to 1D) arranged in a polishing level for polishing a substrate, a post-processing lane (2A, 2B) arranged in a post-processing level for performing post-processing including cleaning and drying of the polished substrates, and an elevating transporter (5) for removing the polished substrate from one of the plurality of polishing modules (1A to 1D) and directly transporting it to the post-processing lane (2A, 2B). The post-processing level is an upper level located above the polishing level, or a lower level located below the polishing level. The elevating transporter (5) is arranged at the same distance from the plurality of polishing modules (1A to 1D), and has a holding hand (40) that can be elevated and lowered between the polishing level and the post-processing level.

### TECHNICAL FIELD

The present invention relates to a substrate processing apparatus for polishing and post-processing a substrate, such as wafer or panel, used in semiconductor devices, and more particularly to a substrate processing apparatus that performs polishing and post-processing of a substrate in levels of different heights.

### BACKGROUND ART

In manufacturing of semiconductor devices, many kinds of materials are repeatedly formed in the form of films on a wafer to form a multilayered structure. In order to form the multilayered structure, planarization of a surface of the wafer is important. A polishing apparatus that performs chemical mechanical polishing (CMP) is one solution for planarizing the surface of such wafer.

The polishing apparatus typically includes a polishing table on which a polishing pad is attached, a polishing head for pressing a wafer against the polishing pad on the polishing table, and a nozzle for supplying a polishing liquid onto the polishing pad. While the polishing liquid is supplied from the nozzle onto the polishing pad, the polishing head presses the wafer against the polishing pad. The polishing head and the polishing pad are moved relative to each other to polish the wafer.

A substrate processing apparatus includes, in addition to the polishing apparatus, a cleaning apparatus for cleaning the polished wafer and a drying apparatus for drying the cleaned wafer. Patent Document 1 discloses a substrate processing apparatus including a plurality of polishing modules, a cleaning module, a drying module, and a transport robot for transporting a polished wafer to the cleaning module. It is necessary to transport the wafer polished by the polishing module to the cleaning module as quickly as possible in order to prevent a metal exposed on the surface of the wafer from being corroded by the polishing liquid.

### CITATION LIST

### Patent Literature

Patent document 1: Japanese laid-open patent publication No. 2022-043081

### SUMMARY OF INVENTION

### Technical Problem

However, in the substrate processing apparatus described in the Patent Document 1, the polishing modules are arranged in a row, and a time required to transport the polished wafer to the cleaning module varies for each polishing module. In particular, when a wafer is polished in a polishing module that has a long transport distance to the cleaning module, it takes a relatively long time to transport the wafer to the cleaning module, which may cause corrosion of metal exposed on the surface of the wafer.

Therefore, the present invention provides a substrate processing apparatus capable of transporting substrates from a plurality of polishing modules to a cleaning module at the same time.

### Solution to Problem

In an embodiment, there is provided a substrate processing apparatus comprising: a plurality of polishing modules each configured to polish a substrate, the plurality of polishing modules being located in a polishing level; a post-processing lane configured to perform post-processing including cleaning and drying of the polished substrate, the post-processing lane being located in a post-processing level; and an elevating transporter configured to remove the polished substrate from one of the plurality of polishing modules and transport the polished substrate directly to the post-processing lane, wherein the post-processing level is an upper level located above the polishing level or a lower level located below the polishing level, the elevating transporter is located at the same distance from the plurality of polishing modules, and the elevating transporter includes a holding hand configured to hold the substrate and an elevating mechanism configured to elevate and lower the holding hand between the polishing level and the post-processing level.

In an embodiment, the plurality of polishing modules comprise four polishing modules, and the elevating transporter is located at the same distance from the four polishing modules and is surrounded by the four polishing modules.

In an embodiment, the elevating transporter further includes an inverting device configured to invert the holding hand.

In an embodiment, the substrate processing apparatus further comprises: a substrate transfer robot configured to remove the substrate to be polished from a cassette storage, remove the post-processed substrate from the post-processing lane, and return the post-processed substrate to the cassette storage; and a vertical movement mechanism configured to elevate and lower the substrate transfer robot between the polishing level and the post-processing level.

In an embodiment, the post-processing lane comprises a first post-processing lane, the substrate processing apparatus further comprises a second post-processing lane arranged in the post-processing level, and the elevating transporter is located at the same distance from the first post-processing lane and the second post-processing lane.

In an embodiment, each of the first post-processing lane and the second post-processing lane includes a cleaning module and a drying module arranged in a row.

In an embodiment, the first post-processing lane and the second post-processing lane are adjacent to the substrate transfer robot.

In an embodiment, each of the plurality of polishing modules has a polishing head configured to polish the substrate and a substrate loader configured to receive the substrate from the elevating transporter and transfer the substrate to the polishing head, and the elevating transporter is located at the same distance from the substrate loaders of the plurality of polishing modules.

In an embodiment, the plurality of polishing modules comprise six polishing modules, the elevating transporter is a first elevating transporter, the first elevating transporter is located at the same distance from at least three of the plurality of polishing modules, the substrate processing apparatus further comprises: a second elevating transporter located at the same distance from remaining polishing modules of the plurality of polishing modules, a third post-processing lane arranged in the post-processing level, and a return transporter configured to transport the substrate that was post-processed by the third post-processing lane to the substrate transfer robot, and the second elevating transporter is configured to remove the polished substrate from one of the remaining polishing modules and transport the polished substrate directly to the third post-processing lane.

### Advantageous Effects of Invention

According to the present invention, the elevating transporter is disposed at the same distance from the plurality of polishing modules. Therefore, a substrate polished in any of the plurality of polishing modules is transported to the post-processing lane in the same transport time. As a result, the substrate processing apparatus can quickly perform post-processing (including cleaning and drying) on the polished substrate. Furthermore, the post-processing level where the post-processing (including cleaning and drying) of the polished substrate is performed is located above or below the polishing level where the substrate is polished, so that an overall installation area of the substrate processing apparatus can be reduced.

### BRIEF DESCRIPTION OF DRAWINGS

FIG. 1 is a perspective view showing an embodiment of a substrate processing apparatus;

FIG. 2 is a diagram showing an embodiment of an elevating transporter;

FIG. 3 is a side view showing the substrate processing apparatus shown in FIG. 1;

FIG. 4 is a top view showing a polishing level of the substrate processing apparatus shown in FIG. 1;

FIG. 5 is a top view showing a post-processing level of the substrate processing apparatus shown in FIG. 1;

FIG. 6A is a plan view showing a post-processing transporter of a first post-processing lane;

FIG. 6B is a plan view showing the post-processing transporter of the first post-processing lane;

FIG. 6C is a plan view showing the post-processing transporter of the first post-processing lane;

FIG. 7 is a perspective view showing another embodiment of the substrate processing apparatus;

FIG. 8 is a perspective view showing yet another embodiment of the substrate processing apparatus;

FIG. 9 is a side view of the substrate processing apparatus shown in FIG. 8;

FIG. 10 is a top view showing a polishing level of the substrate processing apparatus shown in FIG. 8;

FIG. 11 is a top view showing a post-processing level of the substrate processing apparatus shown in FIG. 8;

FIG. 12 is a perspective view showing an embodiment of a return transporter;

FIG. 13 is a top view showing yet another embodiment of a polishing level of the substrate processing apparatus; and

FIG. 14 is a perspective view showing yet another embodiment of the substrate processing apparatus.

### DESCRIPTION OF EMBODIMENTS

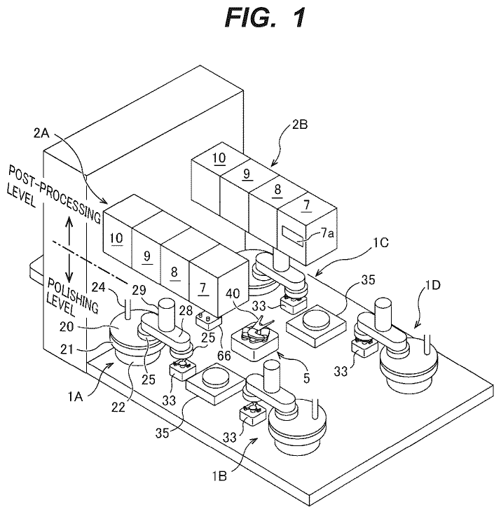

Hereinafter, embodiments of the present invention will be described with reference to the drawings. FIG. 1 is a perspective view showing an embodiment of a substrate processing apparatus. As shown in FIG. 1, the substrate processing apparatus has a multi-level configuration including a polishing level and a post-processing level. The substrate processing apparatus includes a plurality of polishing modules 1A, 1B, 1C, and 1D arranged in the polishing level each configured to polish a substrate, post-processing lanes 2A and 2B arranged in the post-processing level each configured to perform post-processing including cleaning and drying on the polished substrate, and an elevating transporter 5 configured to remove the polished substrate from one of the polishing modules 1A to 1D and directly carry the polished substrate into the post-processing lanes 2A and 2B. Specific examples of the substrate include a wafer and a panel. In the embodiments described below, a circular wafer is used as the substrate.

In the embodiment shown in FIG. 1, four polishing modules 1A to 1D are arranged in the polishing level. The number of polishing modules is not limited to this embodiment, and two or three polishing modules, or five or more polishing modules may be provided.

In this embodiment, the polishing level is a lower level (i.e., a first level), and the post-processing level is an upper level (i.e., a second level) located over the polishing level. Thus, the substrate processing apparatus of this embodiment has a two-level configuration. The post-processing level, where the post-processing (including cleaning and drying) of the polished substrate is performed, is located above the polishing level where polishing of the substrate is performed, so that an overall installation area of the substrate processing apparatus can be reduced. The elevating transporter 5 is disposed at the same distance from the four polishing modules A to 1D and is surrounded by the four polishing modules 1A to 1D. In other words, the elevating transporter 5 is located in the center of the four polishing modules 1A to 1D.

The substrate processing apparatus of the embodiment shown in FIG. 1 has a first post-processing lane 2A and a second post-processing lane 2B. The first post-processing lane 2A and the second post-processing lane 2B are arranged in parallel at the same height in the post-processing level. The first post-processing lane 2A and the second post-processing lane 2B extend in a longitudinal direction of the substrate processing apparatus. Each of the first post-processing lane 2A and the second post-processing lane 2B includes three cleaning modules 7, 8, and 9 and one drying module 10. However, the number of cleaning modules and the number of drying modules included in each of the post-processing lanes 2A and 2B are not limited to this embodiment. In one embodiment, a single post-processing lane may be provided. In another embodiment, each post-processing lane may include only a single post-processing module that cleans and dries a substrate.

The elevating transporter 5 has a holding hand 40 that can move between the polishing level and the post-processing level. Specifically, the holding hand 40 of the elevating transporter 5 removes a polished substrate from one of the four polishing modules 1A to 1D, moves upward together with the substrate from the polishing level to the post-processing level, and then directly carries the substrate into the cleaning module 7 of the first post-processing lane 2A or the second post-processing lane 2B. The cleaning module 7 has an opening 7a in its front wall that allows entrance of the substrate and the holding hand 40 of the elevating transporter 5. The polished substrate is transported into the cleaning module 7 directly (i.e., without being placed onto a temporary stand, etc.) by the elevating transporter 5, so that a transport time of the polished substrate can be shortened. After the substrate is transported into the cleaning module 7, the holding hand 40 moves downward from the post-processing level to the polishing level.

The elevating transporter 5 (more specifically, a home position of the holding hand 40) is at the same distance from the four polishing modules 1A, 1B, 1C, 1D (more specifically, a position of a substrate loader 33). Therefore, a plurality of substrates polished in the four polishing modules 1A to 1D are transported to the cleaning module 7 of the first post-processing lane 2A or the second post-processing lane 2B in the same transport time. The post-processing lanes 2A and 2B can quickly perform the post-processing (including cleaning and drying) on the polished substrates. The same distance from the polishing modules 1A, 1B, 1C, 1D to the elevating transporter 5 includes not only completely the same distance from the polishing modules 1A, 1B, 1C, 1D to the elevating transporter 5, but also substantially the same distance from the polishing modules 1A, 1B, 1C, 1D to the elevating transporter 5 as long as the intended object of the present invention, particularly an object of eliminating a variation in the substrate transport time from the polishing to the post-processing, can be achieved.

In this embodiment, two post-processing lanes 2A, 2B are provided for four polishing modules 1A, 1B, 1C, 1D. This arrangement can prevent the post-processing lanes 2A, 2B from becoming a rate-limiting factor for substrate processing.

The four polishing modules 1A to 1D have the same configuration, and therefore, the polishing module 1A will be described in detail below. As shown in FIG. 1, the polishing module 1A has a polishing table 21 configured to support a polishing pad 20, a table motor 22 configured to rotate the polishing table 21, a polishing-liquid supply nozzle 24 configured to supply a polishing liquid onto the polishing pad 20, two polishing heads 25, 25 each configured to press a substrate against the polishing pad 20 to polish the substrate, and polishing-head motors (not shown) configured to rotate the polishing heads 25, 25 about their axes, respectively. The two polishing heads 25, 25 are rotatably supported by a head arm 28, and the polishing-head motors are disposed in the head arm 28. The center of the head arm 28 is supported by a support shaft 29.

The polishing module 1A further includes substrate loader 33 configured to receive the substrate from the elevating transporter 5 and transfers the substrate to one of the two polishing heads 25, 25. The substrate loader 33 is disposed outwardly of the polishing table 21. The elevating transporter 5 is configured to invert the substrate such that a polishing-target surface of the substrate faces downward, and transfers the substrate to the substrate loader 33 with the polishing-target surface of the substrate facing downward.

The polishing module 1A further includes an arm rotation motor (not shown) configured to rotate the head arm 28 and the two polishing heads 25, 25 around the support shaft 29. The arm rotation motor is installed on the head arm 28 or the support shaft 29. When the head arm 28 is rotated by an angle of 180 degrees by the arm rotation motor, one of the two polishing heads 25, 25 is moved to a position above the polishing pad 20, and the other polishing head 25 is moved to a position above the substrate loader 33. The substrate loader 33 is configured to elevate a substrate and transfer the substrate to the polishing head 25 located outside the polishing table 21. Each of the polishing heads 25, 25 is configured to be able to hold the substrate on its lower surface by vacuum suction. In one embodiment, at least one of the polishing modules 1A to 1D may have a single polishing head.

The substrate is polished as follows. When the substrate to be polished is held by the polishing head 25, the head arm 28 is rotated by 180 degrees, until the polishing head 25 moves together with the substrate to the position above the polishing pad 20. The polishing table 21 and the polishing pad 20 are rotated by the table motor 22, and the polishing liquid (typically a slurry) is supplied onto the polishing pad 20 from the polishing-liquid supply nozzle 24. The polishing head 25 presses a lower surface (polishing-target surface) of the substrate against the polishing pad 20 while the polishing head 25 is rotated by the polishing-head motor (not shown) disposed in the head arm 28. The lower surface of the substrate is polished by a combination of a chemical action of the polishing liquid and a mechanical action of the abrasive grains contained in the polishing liquid and/or the polishing pad 20. The polishing modules 1A to 1D of this embodiment are chemical mechanical polishing apparatuses (CMP apparatuses) each configured to chemically and mechanically polish a substrate.

When polishing of the substrate is terminated, the head arm 28 is rotated by 180 degrees, until the polishing head 25 moves together with the polished substrate to the position above the substrate loader 33. The polishing head 25 releases the substrate, which is placed on the substrate loader 33. The holding hand 40 of the elevating transporter 5 removes the substrate from the substrate loader 33 and moves upward together with the substrate to transfer the substrate into the post-processing lane 2A or 2B.

The substrate processing apparatus of this embodiment further includes a pre-cleaning device 35 configured to pre-clean the substrate before the substrate is polished. The substrate to be polished is transported to the pre-cleaning device 35 by the elevating transporter 5, and the polishing-target surface of the substrate is cleaned by the pre-cleaning device 35. The holding hand 40 of the elevating transporter 5 transports the substrate to the pre-cleaning device 35 with the polishing-target surface of the substrate facing upward. The pre-cleaning device 35 then cleans the polishing-target surface of the substrate. The type of the pre-cleaning device 35 is not particularly limited, and examples of the pre-cleaning device 35 include a buff cleaning device and a scrub cleaning device. The pre-cleaning device 35 can remove particles from the substrate to be polished and can prevent scratches on the substrate in the subsequent polishing of the substrate.

The pre-cleaned substrate is removed from the pre-cleaning device 35 by the holding hand 40 of the elevating transporter 5 and transported to any one of the four polishing modules 1A to 1D. In one embodiment, the pre-cleaning device 35 may not be provided.

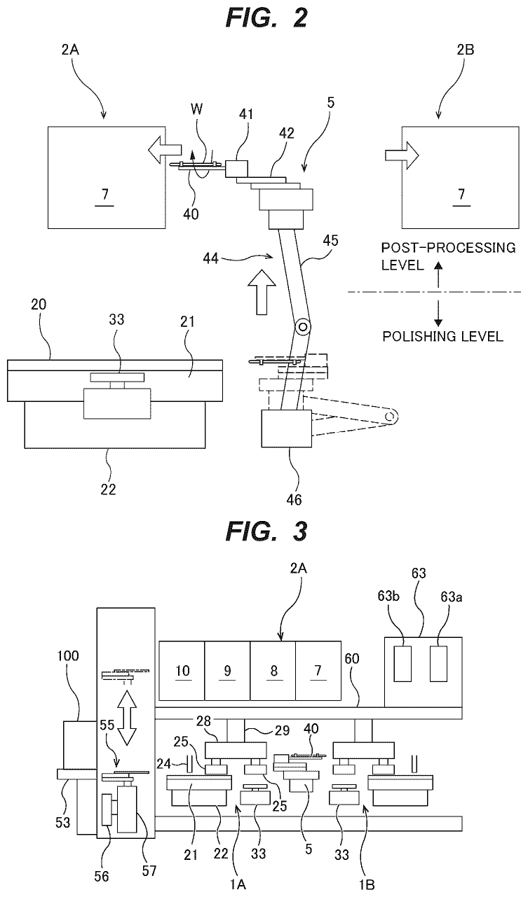

FIG. 2 is a diagram showing an embodiment of the elevating transporter 5. As shown in FIG. 2, the elevating transporter 5 includes the holding hand 40 configured to hold a substrate W, an inverting device 41 configured to invert the holding hand 40, a robot arm 42 to which the inverting device 41 is fixed, and an elevating mechanism 44 configured to elevate and lower the holding hand 40, the inverting device 41, and the robot arm 42 between the polishing level and the post-processing level. The holding hand 40 is configured to hold a periphery of the substrate W, so that the substrate W does not fall from the holding hand 40 when the substrate W and the holding hand 40 are inverted by the inverting device 41. The inverting device 41 is configured to rotate the holding hand 40 holding the substrate W about a horizontal axis until the substrate W is inverted.

The elevating mechanism 44 includes a link mechanism 45 and a link actuator 46 configured to drive the link mechanism 45. One end of the link mechanism 45 is coupled to the robot arm 42, and the other end of the link mechanism 45 is coupled to the link actuator 46. When the link actuator 46 drives the link mechanism 45, the link mechanism 45 expands and contracts in the vertical direction, thereby allowing the holding hand 40, the inverting device 41, and the robot arm 42 to move between the polishing level and the post-processing level. In this embodiment, the holding hand 40, the inverting device 41, and the robot arm 42 provide an elevating stage that moves up and down together with the substrate.

The elevating mechanism 44 is not limited to the combination of the link mechanism 45 and the link actuator 46 of this embodiment, so long as the elevating mechanism 44 can elevate and lower the holding hand 40, the inverting device 41, and the robot arm 42 between the polishing level and the post-processing level. For example, the elevating mechanism 44 may be a traveling robot that can move up and down along a vertical shaft, or may be a combination of a ball screw mechanism and a motor, or may be a linear motor.

The substrate W, with its polishing-target surface facing upward, is transported to the substrate processing apparatus. The inverting device 41 of the elevating transporter 5 inverts the substrate W such that its polishing-target surface faces downward, and then places the substrate W on the substrate loader 33 of any of the polishing modules 1A to 1D. The substrate W that was polished by any of the polishing modules 1A to 1D is released from the polishing head 25 onto the substrate loader 33 with the polished surface facing downward. The holding hand 40 of the elevating transporter 5 removes the polished substrate W from the substrate loader 33. The inverting device 41 of the elevating transporter 5 then inverts the holding hand 40 and the substrate W such that the polished surface faces upward.

The elevating mechanism 44 of the elevating transporter 5 elevates the holding hand 40 holding the substrate W to the post-processing level. The inversion of the substrate W may be performed before, during, or after the elevation of the substrate W. The elevating transporter 5 transports the substrate W into the cleaning module 7 of the first post-processing lane 2A or the second post-processing lane 2B with the polished surface facing upward. The holding hand 40 moves into the cleaning module 7 and passes the substrate W to a substrate holding mechanism (e.g., a holding chuck) in the cleaning module 7.

In this way, the elevating transporter 5 can perform a series of operations including removing the substrate W from the polishing modules 1A to 1D, inverting the substrate W, elevating the substrate W, and transporting the substrate W into the cleaning module 7, thereby shortening the transport time of the polished substrate W from the polishing modules 1A to 1D to the cleaning module 7.

FIG. 3 is a side view showing the substrate processing apparatus shown in FIG. 1. In FIG. 3, the pre-cleaning device 35 is not depicted. As shown in FIG. 3, the substrate processing apparatus further includes a cassette loader 53 on which a cassette storage 100 storing a plurality of substrates therein is placed, and a substrate transfer robot 55 configured to remove one substrate to be polished from the cassette storage 100 and transfer the substrate to the elevating transporter 5. The substrate transfer robot 55 is disposed between the cassette loader 53 and the elevating transporter 5. The substrate processing apparatus further includes a horizontal movement mechanism 56 and a vertical movement mechanism 57 configured to move the substrate transfer robot 55 horizontally and vertically. The vertical movement mechanism 57 is configured to elevate and lower the substrate transfer robot 55 between the polishing level and the post-processing level. Specifically, the substrate transfer robot 55 is elevated to the post-processing level by the vertical movement mechanism 57, removes the post-processed substrate from the post-processing lane 2A or 2B, and is then lowered to the polishing level together with the post-processed substrate by the vertical movement mechanism 57 to return the substrate to the cassette storage 100.

The polishing heads 25, 25 are suspended from a frame 60 located between the polishing level and the post-processing level. More specifically, the polishing module 1A has the support shaft 29 extending downward from the frame 60, and the head arm 28 is rotatably supported by a lower portion of the support shaft 29. The arm rotation motor (not shown) is installed on the head arm 28 or the support shaft 29 so that the arm rotation motor can rotate the head arm 28 and the two polishing heads 25, 25 about the support shaft 29. The other polishing modules 1B, 1C, 1D have the same configuration.

As shown in FIG. 3, the substrate processing apparatus includes an operation controller 63 configured to control the operation of each component including the polishing modules 1A to 1D, the substrate transfer robot 55, the horizontal movement mechanism 56, the vertical movement mechanism 57, the elevating transporter 5, the substrate loader 33, the cleaning modules 7, 8, and 9, and the drying module 10. The operation controller 63 is composed of at least one computer. The operation controller 63 includes a memory 63a storing therein a program for controlling the operation of the substrate processing apparatus, and a processor 63b configured to perform arithmetic operations according to instructions contained in the program. The memory 63a includes a main memory, such as a random access memory (RAM), and an auxiliary memory, such as a hard disk drive (HDD) or a solid state drive (SSD). Examples of the processor 63b include a CPU (central processing unit) and a GPU (graphic processing unit). However, the specific configuration of the operation controller 63 is not limited to these examples.

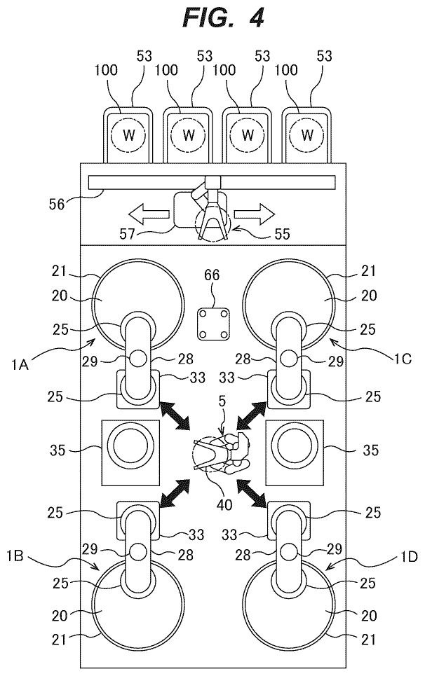

FIG. 4 is a top view showing the polishing level of the substrate processing apparatus shown in FIG. 1. As shown in FIG. 4, the four polishing modules 1A to 1D are not arranged in a row, and are arranged to form a rectangle when viewed from above the substrate processing apparatus. Specifically, the polishing modules 1A and 1B are parallel to the polishing modules 1C and 1D. The polishing modules 1A, 1B and the polishing modules 1C, 1D are arranged symmetrically with respect to the elevating transporter 5.

Since the distances from the substrate loaders 33 of the four polishing modules 1A to 1D to the elevating transporter 5 are the same, a time from when the substrate is released from the polishing head 25 to when the substrate is cleaned can be made the same.

The four polishing modules 1A to 1D have the same configuration, so that distances between the polishing positions of substrates and the substrate loaders 33 are also the same. Therefore, a time from when the substrate is polished to when the substrate is cleaned can be made the same.

The substrate loaders 33 of the four polishing modules 1A to 1D, the polishing positions of substrates, and the polishing tables 21 are symmetrical with respect to the elevating transporter 5 in the longitudinal direction and the width direction of the substrate processing apparatus.

The distance between the substrate loader 33 and the elevating transporter 5 is shorter than the distance between the polishing position of the substrate and the elevating transporter 5. Therefore, there is no waste in transporting the substrate, and a throughput is increased.

The elevating transporter 5 (more specifically, the home position of the holding hand 40) is located at the same distance from the four polishing modules 1A to 1D (more specifically, the positions of the substrate loaders 33). Specifically, the elevating transporter 5 is disposed at the center of the four polishing modules 1A to 1D. Therefore, the elevating transporter 5 can transport a plurality of substrates polished in the four polishing modules 1A to 1D to the post-processing lanes 2A, 2B in the same transport time.

The substrate processing apparatus includes a temporary stage 66 disposed between the elevating transporter 5 and the substrate transfer robot 55. A substrate to be polished is removed from the cassette storage 100 by the substrate transfer robot 55 and placed on the temporary stage 66 by the substrate transfer robot 55. The elevating transporter 5 removes the substrate from the temporary stage 66 and transports the substrate to one of the two pre-cleaning devices 35. The substrate that was pre-cleaned is transported by the elevating transporter 5 to the substrate loader 33 of one of the four polishing modules 1A to 1D.

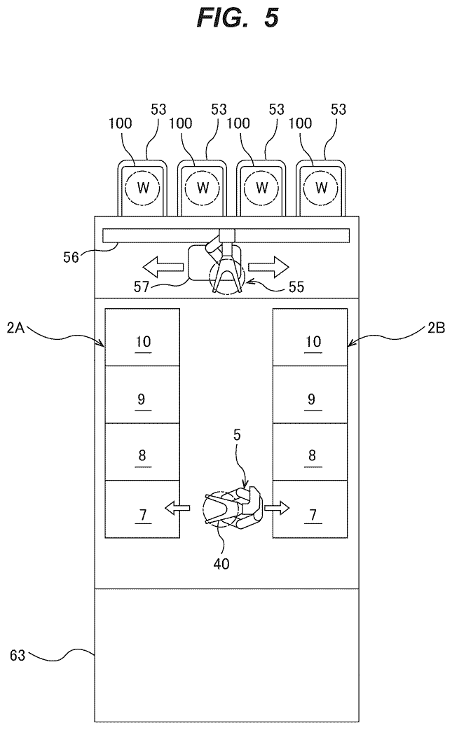

FIG. 5 is a top view showing the post-processing level of the substrate processing apparatus shown in FIG. 1. As shown in FIG. 5, each of the first post-processing lane 2A and the second post-processing lane 2B includes the cleaning module 7, the cleaning module 8, the cleaning module 9, and the drying module 10. It is noted, however, that the number of cleaning modules and the number of drying modules included in each of the post-processing lanes 2A and 2B are not limited to this embodiment. In one embodiment, a single post-processing lane may be provided. In another embodiment, each post-processing lane may include only a single post-processing module that cleans and dries a substrate. Each of the cleaning module 7, the cleaning module 8, the cleaning module 9, and the drying module 10 is a processing module of single-wafer processing type which is configured to process substrates one by one. Therefore, each of the cleaning module 7, the cleaning module 8, the cleaning module 9, and the drying module 10 includes a holding chuck (not shown) for holding a substrate.

The elevating transporter 5 (more specifically, the home position of the holding hand 40) is located at the same distance from the first post-processing lane 2A (e.g., the position of the holding chuck of the cleaning module 7) and the second post-processing lane 2B (e.g., the position of the holding chuck of the cleaning module 7). When viewed from above the substrate processing apparatus, the cleaning module 7 of the first post-processing lane 2A and the cleaning module 7 of the second post-processing lane 2B are arranged symmetrically with respect to the elevating transporter 5. The same distance from the elevating transporter 5 to the first post-processing lane 2A and the second post-processing lane 2B includes not only completely the same distance from the elevating transporter 5 to the first post-processing lane 2A and the second post-processing lane 2B but also substantially the same distance from the elevating transporter 5 to the first post-processing lane 2A and the second post-processing lane 2B, as long as the intended object of the present invention, particularly the object of eliminating the variation in the substrate transport time from the polishing to the post-processing, can be achieved.

The types of cleaning modules 7, 8, and 9 are not particularly limited. In one example, the cleaning module 7 is a buff cleaning device, the cleaning module 8 is a sponge scrub cleaning device, and the cleaning module 9 is a two-fluid jet cleaning device. Cleaning mechanisms of the cleaning modules 7, 8, and 9 can use known configurations. The type of drying module 10 is also not particularly limited. For example, the drying module 10 may be an IPA drying device that sprays isopropyl alcohol vapor onto a substrate to dry the substrate, or may be a spin drying device that removes liquid from a substrate by rotating the substrate at high speed.

The first post-processing lane 2A and the second post-processing lane 2B are adjacent to the substrate transfer robot 55. The cleaning module 7, the cleaning module 8, the cleaning module 9, and the drying module 10 are arranged in a row. The elevating transporter 5 is operable to transport the substrate into the cleaning module 7, which is located at the farthest position from the substrate transfer robot 55. The drying module 10 is closer to the substrate transfer robot 55 than the three cleaning modules 7, 8, and 9.

The polished substrate is transported by a post-processing transporter (which will be described later) to the cleaning module 7, the cleaning module 8, the cleaning module 9, and the drying module 10 in this order, so that the post-processing including cleaning and drying is performed on the substrate. The substrate dried by the drying module 10 is removed from the drying module 10 by the substrate transfer robot 55 and returned to the cassette storage 100 shown in FIG. 3.

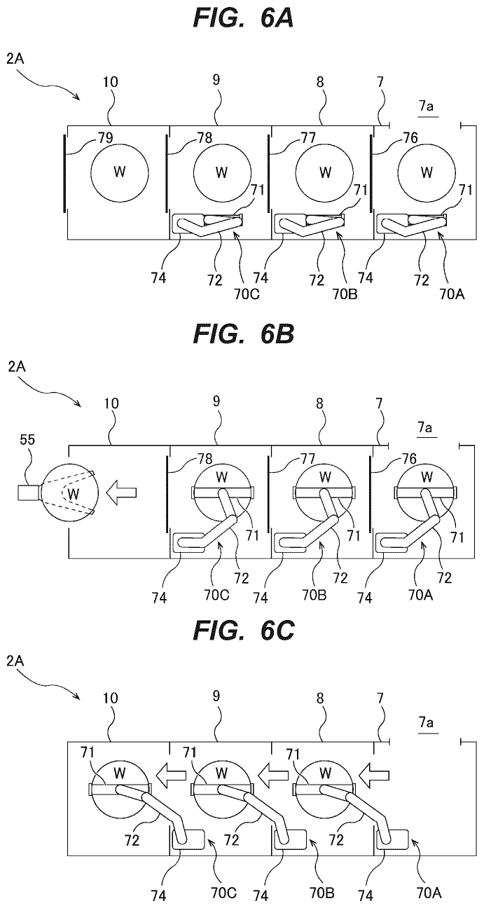

FIGS. 6A to 6C are plan views showing the post-processing transporter of the first post-processing lane 2A. As shown in FIG. 6A to FIG. 6C, the first post-processing lane 2A includes three post-processing transporters 70A, 70B, and 70C. These three post-processing transporters 70A, 70B, and 70C are arranged in the three cleaning modules 7, 8, and 9, respectively. The drying module 10 is not provided with a post-processing transporter. The number of post-processing transporters 70A, 70B, and 70° C. corresponds to the number of cleaning modules 7, 8, and 9. Specifically, in this embodiment, three cleaning modules 7, 8, and 9 are provided, and therefore, three post-processing transporters 70A, 70B, and 70C are provided. In an embodiment in which two cleaning modules are provided, two post-processing transporters are provided. A front wall of the cleaning module 7 has the opening 7a that allows the holding hand 40 (see FIG. 2) of the elevating transporter 5 to enter.

The three post-processing transporters 70A, 70B, and 70C have the same configuration, and therefore, the post-processing transporter 70A will be described below. The post-processing transporter 70A includes a clamp 71 configured to hold the substrate W, a link arm 72 coupled to the clamp 71, and an arm actuator 74 configured to drive the link arm 72. FIG. 6A shows a state in which substrates W are cleaned and dried in the cleaning modules 7, 8, and 9 and the drying module 10. The clamps 71 and the link arms 72 are in retreat positions. Shutters 76, 77, 78, and 79 are provided on side walls of the cleaning modules 7, 8, and 9 and side wall of the drying module 10. The shutters 76, 77, 78, and 79 are closed during cleaning and drying of the substrates W, as shown in FIG. 6A. The opening 7a is also closed by a shutter (not shown) during cleaning and drying of the substrate W.

As shown in FIG. 6B, when cleaning and drying of the substrate W is terminated, the shutter 79 of the drying module 10 is opened, and the substrate transfer robot 55 removes the substrate W from the drying module 10. Next, the clamps 71 of the three post-processing transporters 70A, 70B, 70C hold the three substrates W in the cleaning modules 7, 8, 9, respectively. Then, as shown in FIG. 6C, the shutters 76, 77, 78 of the cleaning modules 7, 8, 9 are opened, and the three post-processing transporters 70A, 70B, 70C transport the substrates W to the next cleaning modules 8, 9 and the drying module 10.

The operations of the post-processing transporters 70A, 70B, and 70C are controlled by the operation controller 63 (see FIG. 3). The three post-processing transporters 70A, 70B, and 70C may transport the three substrates W simultaneously, or may transport the substrates W at different times after the substrates W are removed from the next cleaning module 8 or 9 or the drying module 10.

The specific configuration of the post-processing transporters 70A, 70B, and 70C is not limited to the embodiment shown in FIGS. 6A to 6C as long as the intended functions of the post-processing transporters 70A, 70B, and 70C can be achieved.

Next, an example of the operation of polishing, cleaning, and drying a substrate will be described. The operation controller 63 (see FIG. 3) instructs the components of the substrate processing apparatus including the polishing modules 1A to 1D, the substrate transfer robot 55, the horizontal movement mechanism 56, the vertical movement mechanism 57, the elevating transporter 5, the pre-cleaning device 35, the substrate loader 33, the cleaning modules 7, 8, and 9, the drying module 10, and the post-processing transporters 70A, 70B, and 70C, to perform the operations described below. In the example described below, a two-step polishing of the substrate is performed, including a first polishing and a second polishing using two of the four polishing modules 1A to 1D.

Substrates are stored in the cassette storage 100 with their polishing-target surfaces facing upward. The substrate transfer robot 55 removes one substrate from the cassette storage 100 on the cassette loader 53 and places the substrate on the temporary stage 66. The holding hand 40 of the elevating transporter 5 removes the substrate from the temporary stage 66 and transports the substrate to the pre-cleaning device 35. The pre-cleaning device 35 cleans the polishing-target surface of the substrate with the polishing-target surface facing upward. When the pre-cleaning of the substrate is terminated, the holding hand 40 of the elevating transporter 5 removes the substrate from the pre-cleaning device 35. The inverting device 41 of the elevating transporter 5 reverses the holding hand 40 holding the substrate until the polishing-target surface of the substrate faces downward. Then, the elevating transporter 5 places the substrate on one of the substrate loaders 33 of the four polishing modules 1A to 1D.

The substrate loader 33 elevates the substrate up to the polishing head 25, which holds the substrate on its lower surface by vacuum suction. The head arm 28 is rotated by an angle of 180 degrees, so that the polishing head 25 holding the substrate is moved to the position above the polishing pad 20. While the polishing pad 20 and the polishing table 21 are rotated, the polishing liquid is supplied onto the polishing pad 20 from the polishing-liquid supply nozzle 24. While the polishing head 25 is rotated around its axis, the polishing head 25 presses the polishing-target surface (lower surface) of the substrate against the polishing pad 20. The polishing-target surface of the substrate is brought into sliding contact with the polishing pad 20 in the presence of the polishing liquid. The substrate is polished by a combination of the chemical action of the polishing liquid and the mechanical action of the abrasive grains contained in the polishing liquid and/or the polishing pad 20 (first polishing of the substrate).

After polishing of the substrate is terminated, the head arm 28 is rotated by an angle of 180 degrees, so that the polishing head 25 holding the polished substrate is moved to the position above the substrate loader 33. The substrate loader 33 rises and receives the substrate from the polishing head 25, and then the substrate loader 33 descends together with the substrate. The elevating transporter 5 receives the polished substrate from the substrate loader 33, and transports the substrate with its polished surface facing downward to one of the other polishing modules 1B, 1C, 1D. The substrate is then further polished by the other polishing module (second polishing of the substrate).

In this way, the first polishing and the second polishing of the substrate are performed consecutively. When the second polishing of the substrate is terminated, the holding hand 40 of the elevating transporter 5 removes the substrate from the substrate loader 33 of the polishing module that performed the second polishing. Thereafter, the inverting device 41 of the elevating transporter 5 inverts the holding hand 40 holding the substrate until the polished surface of the substrate faces upward. The elevating mechanism 44 of the elevating transporter 5 elevates the holding hand 40 holding the substrate from the polishing level to the post-processing level, and the holding hand 40 transports the substrate to the cleaning module 7 (more specifically, the holding chuck of the cleaning module 7) of the first post-processing lane 2A or the second post-processing lane 2B. The inversion of the substrate may be performed before, during, or after the elevation of the substrate.

The cleaning module 7 cleans the substrate. After the cleaning of the substrate, the post-processing transporter 70A shown in FIGS. 6A to 6C transports the substrate from the cleaning module 7 to the cleaning module 8. The cleaning module 8 further cleans the substrate. The post-processing transporter 70B shown in FIGS. 6A to 6C then transports the substrate from the cleaning module 8 to the cleaning module 9. The cleaning module 9 further cleans the substrate. The post-processing transporter 70C shown in FIGS. 6A to 6C then transports the substrate from the cleaning module 9 to the drying module 10. The drying module 10 dries the cleaned substrate.

Thereafter, the substrate transfer robot 55 removes the dried substrate from the drying module 10. The vertical movement mechanism 57 lowers the substrate transfer robot 55 together with the substrate from the post-processing level to the polishing level, and the substrate transfer robot 55 returns the substrate to the cassette storage 100. In this manner, the substrate is polished, cleaned, and dried.

In one embodiment, the substrate processing apparatus may perform three-step polishing using three of the four polishing modules 1A to 1D, or may perform four-step polishing using all of the four polishing modules 1A to 1D. Furthermore, in one embodiment, the substrate processing apparatus may perform one-step parallel polishing in which four substrates are polished in parallel using the four polishing modules 1A to 1D.

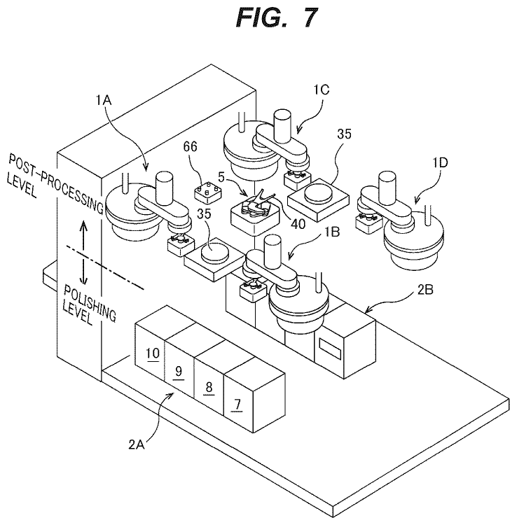

In each of the above-described embodiments, the polishing level is a lower level (i.e., the first level) and the post-processing level is an upper level (i.e., the second level) located above the polishing level, while in one embodiment, as shown in FIG. 7, the polishing level may be an upper level and the post-processing level may be a lower level located below the polishing level.

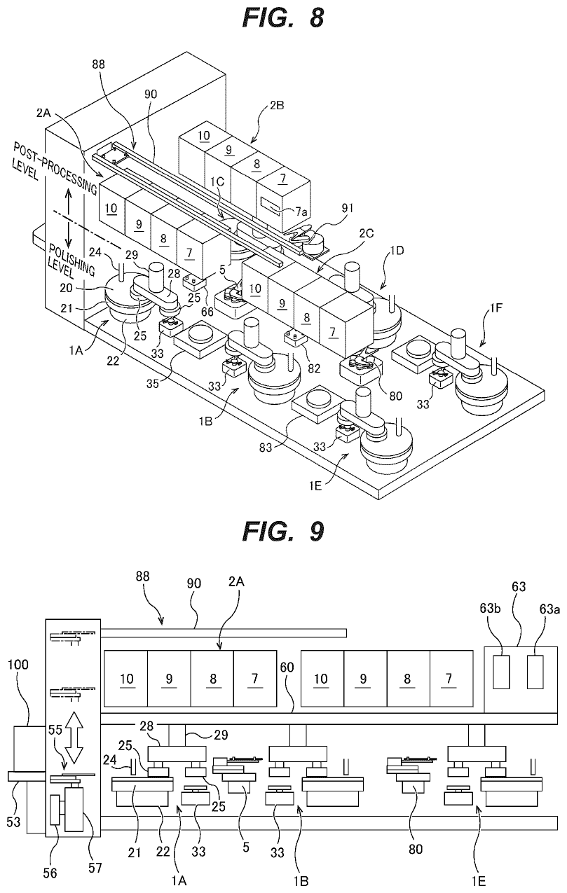

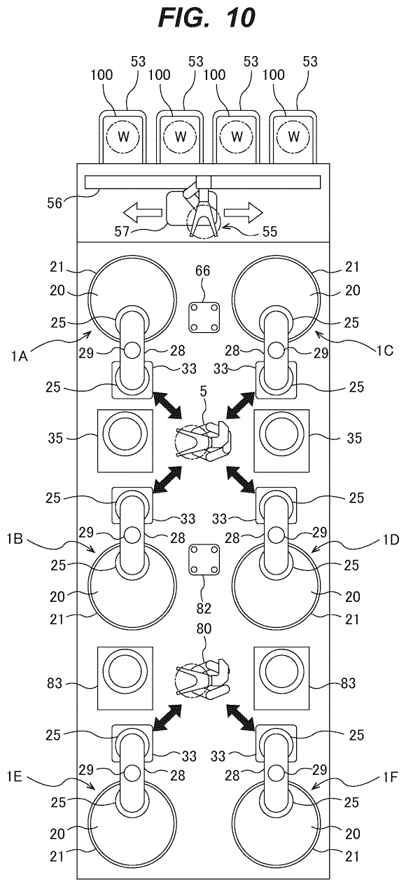

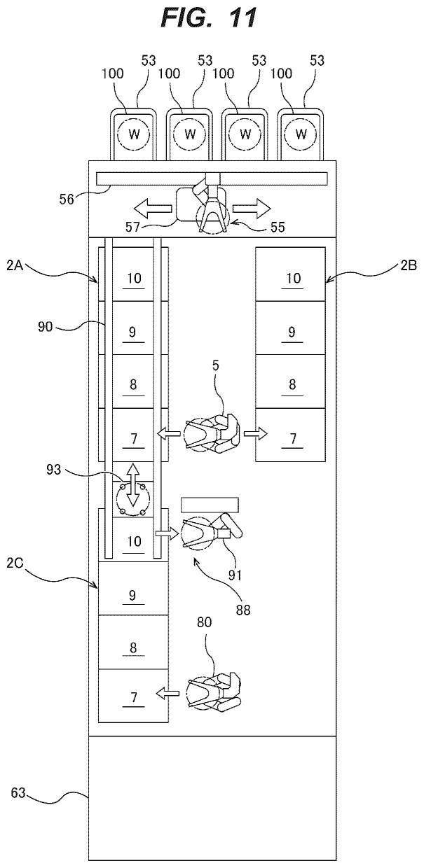

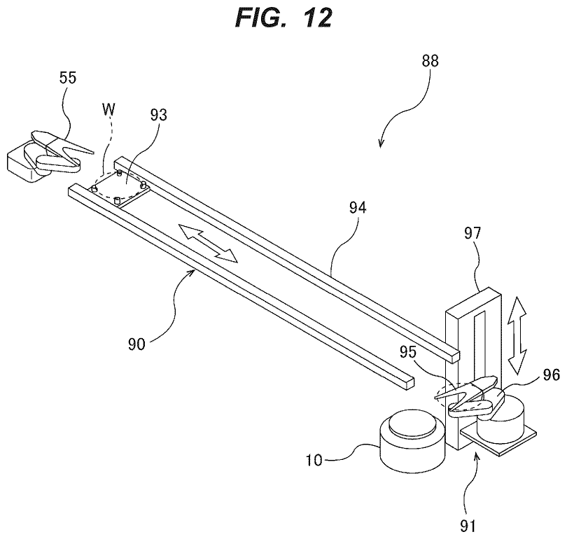

Next, another embodiment of the substrate processing apparatus will be described. FIG. 8 is a perspective view showing yet another embodiment of the substrate processing apparatus, FIG. 9 is a side view of the substrate processing apparatus shown in FIG. 8, FIG. 10 is a top view showing the polishing level of the substrate processing apparatus shown in FIG. 8, and FIG. 11 is a top view showing the post-processing level of the substrate processing apparatus shown in FIG. 8. Configuration and operation of this embodiment that are not particularly described are the same as those of the embodiments described with reference to FIGS. 1 to 6, so that duplicated description will be omitted.

The substrate processing apparatus of this embodiment has six polishing modules 1A, 1B, 1C, 1D, 1E, and 1F, and two elevating transporters 5 and 80. The six polishing modules 1A to 1F are not arranged in a row, and are arranged to form a rectangle when viewed from above the substrate processing apparatus. Specifically, the polishing modules 1A, 1B, and 1E are parallel to the polishing modules 1C, 1D, and 1F.

The elevating transporter 5 is located at the same distance from the four polishing modules 1A to 1D. The elevating transporter 80 is located at the same distance from the polishing modules 1E and 1F. The same distance from the polishing modules 1E and 1F to the elevating transporter 80 includes not only completely the same distance from the polishing modules 1E and 1F to the elevating transporter 80, but also substantially the same distance from the polishing modules 1E and 1F to the elevating transporter 80 as long as the intended object of the present invention, particularly the object of eliminating the variation in the substrate transport time from the polishing to the post-processing, can be achieved. The polishing modules 1E and 1F are arranged symmetrically with respect to the elevating transporter 80. The distance from each of the polishing modules 1A to 1D to the elevating transporter 5 are the same as the distance from each of the polishing modules 1E and 1F to the elevating transporter 80.

The elevating transporter 5 is used to transport a substrate to and remove a substrate from the four polishing modules 1A to 1D, as well as the embodiments described with reference to FIGS. 1 to 6. The elevating transporter 80 is used to transport a substrate to and remove a substrate from the polishing modules 1E and 1F.

The substrate processing apparatus further includes a temporary stage 82 disposed between the elevating transporter 5 and the elevating transporter 80. A substrate to be polished in the polishing module 1E and/or the polishing module 1F is placed on the temporary stage 82 by the elevating transporter 5, and the elevating transporter 80 removes the substrate from the temporary stage 82 and transports the substrate to the polishing module 1E or the polishing module 1F. Configurations and operations of the polishing module 1E and the polishing module 1F are the same as those of the four polishing modules 1A to 1D described above, and therefore will not be described again.

The substrate processing apparatus further includes pre-cleaning devices 83 adjacent to the polishing modules 1E and 1F. Configurations and operations of these pre-cleaning devices 83 are the same as those of the above-mentioned pre-cleaning device 35, and therefore a duplicated description thereof will be omitted.

The substrate processing apparatus further includes a third post-processing lane 2C arranged in the post-processing level, and a return transporter 88 configured to transport a substrate that was post-processed by the third post-processing lane 2C to the substrate transfer robot 55. The third post-processing lane 2C has three cleaning modules 7, 8, 9, one drying module 10, and three post-processing transporters 70A, 70B, 70C (see FIG. 6), as well as the first post-processing lane 2A and the second post-processing lane 2B. It is noted, however, that the number of cleaning modules and the number of drying modules included in the third post-processing lane 2C are not limited to those in this embodiment.

In this embodiment, configuration of the third post-processing lane 2C is the same as the first post-processing lane 2A and the second post-processing lane 2B. In one embodiment, the substrate processing apparatus may further include a fourth post-processing lane parallel to the third post-processing lane 2C.

The elevating transporter 80 is configured to remove the polished substrate from the polishing module 1E or polishing module 1F and transport the polished substrate directly to the cleaning module 7 of the third post-processing lane 2C. The configuration of the elevating transporter 80 is the same as that of the elevating transporter 5, and therefore, a duplicated description will be omitted. The operations of the polishing modules 1E, 1F, the elevating transporter 80, the return transporting device 88, the pre-cleaning device 83, and the third post-processing lane 2C are controlled by the operation controller 63.

The return transporter 88 includes a linear transporter 90 configured to transport the substrate from the third post-processing lane 2C to the substrate transfer robot 55, and a lifter 91 configured to remove the substrate from the drying module 10 of the third post-processing lane 2C and transfer the substrate to the linear transporter 90. The linear transporter 90 is arranged at a position higher than the first post-processing lane 2A and the second post-processing lane 2B, and the lifter 91 is arranged next to the third post-processing lane 2C. In the embodiment shown in FIG. 8, the linear transporter 90 is located above the first post-processing lane 2A. In one embodiment, the linear transporter 90 may be located above the second post-processing lane 2B, or may be located between the first post-processing lane 2A and the second post-processing lane 2B.

FIG. 12 is a perspective view showing one embodiment of the return transporter 88. As shown in FIG. 12, the linear transporter 90 includes a substrate stage 93 configured to support the substrate W, and a stage moving mechanism 94 extending from the drying module 10 of the third post-processing lane 2C to the substrate transfer robot 55. The stage moving mechanism 94 is configured to move the substrate stage 93 from the drying module 10 of the third post-processing lane 2C to the substrate transfer robot 55. The lifter 91 includes a hand 95 configured to support the substrate W, a robot arm 96 coupled to the hand 95, and a vertical movement mechanism 97 configured to move the hand 95 and the robot arm 96 up and down.

The lifter 91 removes the substrate W from the drying module 10 of the third post-processing lane 2C, elevates the substrate W up to the linear transporter 90, and places the substrate W on the substrate stage 93 of the linear transporter 90. The stage moving mechanism 94 of the linear transporter 90 moves the substrate stage 93 supporting the substrate W to the substrate transfer robot 55. The substrate transfer robot 55 removes the substrate W from the substrate stage 93 and returns the substrate W to the cassette storage 100 (see FIG. 3).

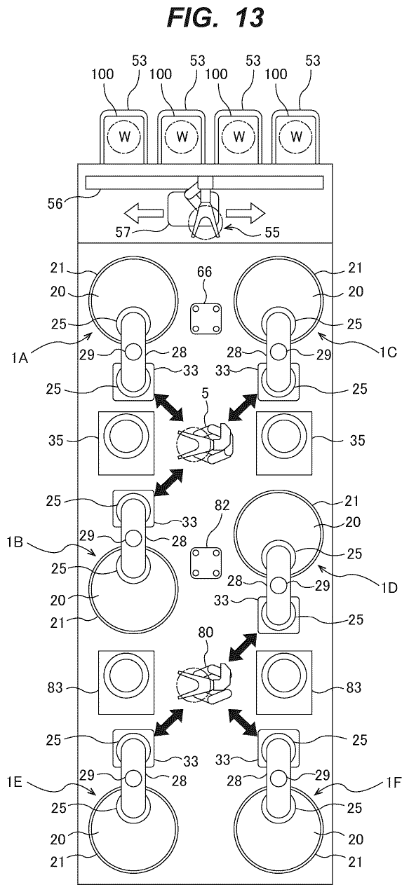

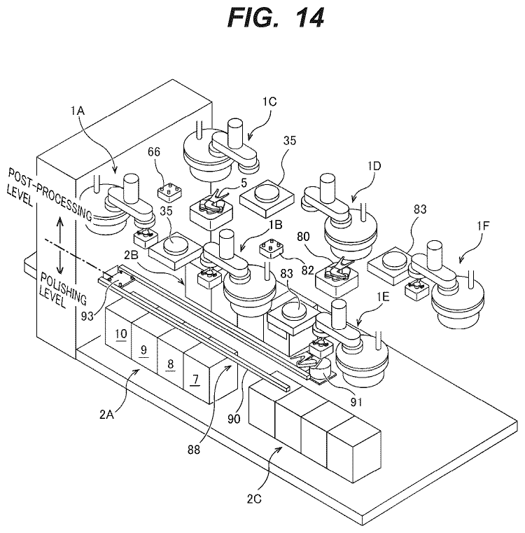

The substrate processing apparatus including the six polishing modules 1A to 1F is capable of processing more substrates. In one embodiment, as shown in FIG. 13, three-step polishing can be performed on two substrates. In the embodiment shown in FIG. 13, the elevating transporter 5 is operable to transport a substrate to and remove the substrate from the polishing modules 1A, 1B, and 1C. The elevating transporter 80 is operable to transport a substrate to and remove the substrate from the polishing modules 1D, 1E, and 1F.

In the embodiments described with reference to FIGS. 8 to 13, the polishing level is a lower level (i.e., the first level) and the post-processing level is an upper level (i.e., the second level) located above the polishing level, while in one embodiment, as shown in FIG. 14, the polishing level may be an upper level and the post-processing level may be a lower level located below the polishing level.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention can be used in a substrate processing apparatus for polishing and post-processing a substrate used in semiconductor devices, such as wafer or panel.

### REFERENCE SIGNS LIST

1A,1B,1C,1D,1E,1F polishing module
2A,2B,2C post-processing lane
5 elevating transporter
7,8,9 cleaning module
7a opening
10 drying module
20 polishing pad
21 polishing table
22 table motor
24 polishing-liquid supply nozzle
25 polishing head
28 head arm
29 support shaft
33 substrate loader
35 pre-cleaning device
40 holding hand
41 inverting device
42 robot arm
44 elevating mechanism
45 link mechanism
46 link actuator
53 cassette loader
55 substrate transfer robot
56 horizontal movement mechanism
57 vertical movement mechanism
60 frame
63 operation controller
63a memory
63b processor
66 temporary stage
70A,70B,70C post-processing transporter
71 clamp
72 link arm
74 arm actuator
76,77,78,79 shutter
80 elevating transporter
82 temporary stage
88 return transporter
90 linear transporter
91 lifter
93 substrate stage
94 stage moving mechanism
95 hand
96 robot arm
97 vertical movement mechanism
100 cassette storage

1. A substrate processing apparatus comprising:
a plurality of polishing modules each configured to polish a substrate, the plurality of polishing modules being located in a polishing level;
a post-processing lane configured to perform post-processing including cleaning and drying of the polished substrate, the post-processing lane being located in a post-processing level; and
an elevating transporter configured to remove the polished substrate from one of the plurality of polishing modules and transport the polished substrate directly to the post-processing lane,
wherein the post-processing level is an upper level located above the polishing level or a lower level located below the polishing level,
the elevating transporter is located at the same distance from the plurality of polishing modules, and
the elevating transporter includes a holding hand configured to hold the substrate and an elevating mechanism configured to elevate and lower the holding hand between the polishing level and the post-processing level.

2. The substrate processing apparatus according to claim 1,
wherein the plurality of polishing modules comprise four polishing modules, and the elevating transporter is located at the same distance from the four polishing modules and is surrounded by the four polishing modules.

3. The substrate processing apparatus according to claim 1,
wherein the elevating transporter further includes an inverting device configured to invert the holding hand.

4. The substrate processing apparatus according to claim 1, further comprising:
a substrate transfer robot configured to remove the substrate to be polished from a cassette storage, remove the post-processed substrate from the post-processing lane, and return the post-processed substrate to the cassette storage; and
a vertical movement mechanism configured to elevate and lower the substrate transfer robot between the polishing level and the post-processing level.

5. The substrate processing apparatus according to claim 4, wherein the post-processing lane comprises a first post-processing lane,
the substrate processing apparatus further comprises a second post-processing lane arranged in the post-processing level, and
the elevating transporter is located at the same distance from the first post-processing lane and the second post-processing lane.

6. The substrate processing apparatus according to claim 5, wherein each of the first post-processing lane and the second post-processing lane includes a cleaning module and a drying module arranged in a row.

7. The substrate processing apparatus according to claim 5, wherein the first post-processing lane and the second post-processing lane are adjacent to the substrate transfer robot.

8. The substrate processing apparatus according to claim 1, wherein each of the plurality of polishing modules has a polishing head configured to polish the substrate and a substrate loader configured to receive the substrate from the elevating transporter and transfer the substrate to the polishing head, and
the elevating transporter is located at the same distance from the substrate loaders of the plurality of polishing modules.

9. The substrate processing apparatus according to claim 5, wherein the plurality of polishing modules comprise six polishing modules,
the elevating transporter is a first elevating transporter,
the first elevating transporter is located at the same distance from at least three of the plurality of polishing modules,
the substrate processing apparatus further comprises:
a second elevating transporter located at the same distance from remaining polishing modules of the plurality of polishing modules,
a third post-processing lane arranged in the post-processing level, and
a return transporter configured to transport the substrate that was post-processed by the third post-processing lane to the substrate transfer robot, and
the second elevating transporter is configured to remove the polished substrate from one of the remaining polishing modules and transport the polished substrate directly to the third post-processing lane.
